(19) United States
(12) Patent Application Publication
(10) Pub. No.: US 2010/0139756 A1
(43) Pub. Date: Jun. 10, 2010

(54) Simultaneously Writing Bus Bars And Gridlines For Solar Cell

(75) Inventor: Stephen Patrick Shea, Savannah, GA (US)

Correspondence Address: BEVER, HOFFMAN & HARMS, LLP, 901 CAMPISI WAY, SUITE 370, CAMPBELL, CA, 95008, US

(73) Assignee: Palo Alto Research Center Incorporated, Palo Alto, CA (US)

(21) Appl. No.: 12/332,279

(22) Filed: Dec. 10, 2008

(51) Int. Cl. H01L 31/00

(52) U.S. Cl. 136/256

(57) ABSTRACT

A method for efficiently producing closely-spaced parallel gridlines and perpendicular bus bar structures on a substrate during a single pass of a multi-nozzle printhead assembly over the substrate. A first section of the parallel gridlines is printed adjacent to one edge of the substrate while moving the printhead assembly in a first direction. The printhead assembly is then reciprocated in a second direction (X-axis) orthogonal to the first direction, whereby the extruded material forms a bus bar structure extending perpendicular to the gridlines. Movement of the printhead assembly in the first direction is then resumed to form a second section of the gridlines. The second direction reciprocation process is repeated for each desired bus bar structure. The entire gridline/bus bar printing process is performed without halting the extrusion of material (i.e., using a continuous bead).

### FIELD OF THE INVENTION

The present invention is related to extrusion systems, and more particularly to micro-extrusion systems for extruding closely spaced lines of material on a substrate.

### BACKGROUND

FIG. 9 is a simplified diagram showing an exemplary conventional solar cell 40 formed on a semiconductor substrate 41 that converts sunlight into electricity by the inner photoelectric effect. Solar cell 40 is formed on a semiconductor substrate 41 that is processed using known techniques to include an n-type (or p-type) doped upper region 41A and an oppositely p-type (or n-type) doped lower region 41B such that a pn-junction is formed near the top of substrate 41. Disposed on an upper surface 42 of semiconductor substrate 41 are a series of parallel metal gridlines (fingers) 44 (shown in end view) that are electrically and mechanically connected to n-type region 41A. A substantially solid conductive layer 46 is formed on a lower surface 43 of substrate 41, and is electrically and mechanically connected to p-type region 41B. An antireflection coating 47 is typically formed over upper surface 42 of substrate 41. Solar cell 40 generates electricity when a solar photon from sunlight beams L1 (with an energy greater than the semiconductor band gap) passes through upper surface 42 into substrate 41 and interacts with a semiconductor material atom. This interaction excites an electron (“−”) in the valence band to the conduction band, allowing the electron and an associated hole (“+”) to flow within substrate 41. The pn-junction separating n-type region 41A and p-type region 41B serves to prevent recombination of the excited electrons with the holes, thereby generating a potential difference that can be applied to a load by way of gridlines 44 and conductive layer 46, as indicated in FIG. 9.

FIG. 10 is a perspective view showing the front contact pattern of solar cell 40 in additional detail. The front contact pattern solar cell 40 consists of a rectilinear array of parallel gridlines 44 and one or more wider collection lines (bus bars) 45 that extend perpendicular to gridlines 44, both disposed on upper surface 42. Gridlines 44 collect electrons (current) from substrate 41 as described above, and bus bars 45 which gather current from gridlines 44. In a photovoltaic module, bus bars 45 become the points to which metal ribbon (not shown) is attached, typically by soldering, with the ribbon being used to electrically connect one cell to another.

Conventional methods for producing the front contact pattern of solar cell 40 typically involve screen-printing both gridlines 44 and bus bars 45 in a single pass using a metal-bearing ink. Conventional screen printing techniques typically produce gridlines having a roughly rectangular cross-section with a width W of approximately 130 μm and a height H of approximately 15 μm, producing an aspect ratio of approximately 0.12. A problem associated with screen printing in the context of solar cells is this relatively low aspect ratio causes gridlines 44 to generate an undesirably large shadowed surface area (i.e., gridlines 44 prevent a significant amount of sunlight from passing through a large area of upper surface 22 into substrate 21, as depicted in FIG. 9 by light beam L2), which reduces the ability of solar cell 20 to generate electricity. However, simply reducing the width of gridlines 44 (i.e., without increasing the gridlines' cross-sectional area by increasing their height dimension) could undesirably limit the current transmitted to the applied load, and forming high aspect ratio gridlines using screen printing techniques would significantly increase production costs.

More recently, a method was introduced for producing front contact patterns for solar cells in which a metal-bearing material is extrusion printed directly onto a semiconductor substrate. Although the extrusion printing method addressed the shadowing problem of screen printed front contact patterns by providing gridlines having relatively high aspect ratios, this alternative production method requires two separate steps: one to apply the gridlines, and a second step, (either previous to or subsequent to the gridline application), to apply the bus bars. For example, as illustrated in FIGS. 11(A) to 11(C), a solar cell 40A similar to that described with reference to FIG. 10 is formed by moving an extrusion printhead (not shown) in a Y-axis direction relative to a substrate 41A while printing bus bars 45A on upper surface 42A (see FIG. 11(A)). Substrate 41A (or the printhead) is then turned 90° as shown in FIG. 11(B)), and then, as shown in FIG. 11(C), gridlines 44A are printed on substrate surface 42A and on bus bars 45A using the printhead. Although providing higher aspect ratio gridlines, advantages of extrusion printing over screen printing are partially offset by the increased process complexity and product handling involved in writing or printing gridlines 44A and bus bars 45A as separate steps, as illustrated in FIGS. 11(A) to 11(C).

Referring again to FIG. 11(C), another problem with extrusion printing the front metallization of conventional H-pattern solar cell 40 is the uneven topography on the bus bars 45 (i.e., where bus bars 45 are crossed by the gridlines 44). This topography does not impact the cell performance, but it can create a weak solder joint between the subsequently applied metal ribbon (not shown) and the top of bus bar 45 because there is insufficient solder to fill in the gaps between gridlines 44.

What is needed is a micro extrusion printing method and associated apparatus for producing solar cells that facilitates the formation of extruded gridlines and bus bars for solar cells at a low cost that is acceptable to the solar cell industry and addresses the problems described above.

### SUMMARY OF THE INVENTION

The present invention is directed to a micro-extrusion system and method for producing solar cells (and other electric electronic and devices) in which a printhead is used to produce continuous lines (beads) that include both straight (gridline) sections and switchback (wavy) sections that are alternately formed on a substrate during a single pass of the printhead assembly over the substrate surface. The straight sections of each continuous line are aligned in a first direction to form a set of parallel gridlines, with each adjacent pair of gridline sections being connected by an associated switchback section. The switchback sections include several connected switchback segments that extend generally in a second direction, and collectively form relatively wide switchback structures that extend generally perpendicular to the gridlines. The invention thus facilitates the formation of the front solar cell metallization pattern (gridlines and buses) using a single pass of an extrusion head, thereby eliminating the added time and cost associated with separate printing steps for gridline and bus bar formation, as required in the prior art. In addition, because the gridline material is deposited during a single pass, the gridlines do not cross the bus bar structures, thereby avoiding the weak solder joint problem associated with conventional extrusion processes.

In accordance with an embodiment of the present invention, a method for forming front beads method involves positioning the printhead assembly over a predetermined region of the substrate (e.g., adjacent to a side edge of the substrate), and starting the extrusion process while moving the printhead assembly at an initial speed in a straight-line first (Y-axis) direction (i.e., while keeping the substrate stationary) for a predetermined distance such that the extruded line forms first gridline sections on the substrate surface. Next, while maintaining relative movement of the printhead assembly and substrate in the first (Y-axis) direction, but at a slower speed, the method involves reciprocating the printhead assembly relative to the substrate in a second (X-axis) direction, whereby the extruded material associated with each gridline forms an associated bus bar section extending in the second (X-axis) direction such that the bus bar sections collectively form a bus bar structure. Upon completing the bus bar structure, the printhead assembly is again moved at the first speed in the in the straight-line first (Y-axis) direction such that the extruded line foams second gridline sections on the substrate surface. The process of alternately forming gridline sections and bus bar structures is repeated to produce as many bus bar structures as desired.

### BRIEF DESCRIPTION OF THE DRAWINGS

These and other features, aspects and advantages of the present invention will become better understood with regard to the following description, appended claims, and accompanying drawings, where:

FIG. 1 is a perspective view showing a simplified extrusion printhead assembly and printed structure formed on a substrate in accordance with an embodiment of the present invention;

FIG. 2 is a side view showing a portion of a micro-extrusion system including a micro-extrusion printhead assembly utilized in accordance with an embodiment of the present invention;

FIG. 3 is a side view showing the micro-extrusion system of FIG. 2 in additional detail;

FIG. 4 is an exploded cross-sectional side view showing generalized micro-extrusion printhead assembly utilized in the system of FIG. 2;

FIG. 5 is a partial side view showing the micro-extrusion printhead assembly of FIG. 4 during operation;

FIG. 6 is a cross-sectional assembled side view showing a portion of the micro-extrusion printhead assembly of FIG. 4 during operation;

FIGS. 7(A), 7(B), 7(C) and 7(D) are partial perspective views showing the system of FIG. 2 during the production of a solar cell in accordance with an embodiment of the present invention;

FIGS. 8(A) and 8(B) are plan views showing printed patterns formed on a substrate in accordance with alternative embodiments of the present invention;

FIG. 9 is a simplified cross-sectional view showing a solar cell during operation;

FIG. 10 is a perspective view showing a conventional solar cell; and

FIGS. 11(A), 11(B) and 11(C) are partial perspective views showing a conventional method for extrusion printing bus lines and grid lines for conventional solar cells.

### DETAILED DESCRIPTION

The present invention relates to an improvement in micro-extrusion systems. The following description is presented to enable one of ordinary skill in the art to make and use the invention as provided in the context of a particular application and its requirements. As used herein, directional terms such as “upper”, “top”, “lower”, “bottom”, “front”, “rear”, and “lateral” are intended to provide relative positions for purposes of description, and are not intended to designate an absolute frame of reference. As used herein, the term “generally perpendicular” is intended to mean that the respective elongated structures are aligned at an angle in the range of 45 to 90 degrees. As used herein, the term “integrally connected” is intended to mean that the related structures are formed during a single fabrication process (e.g., extrusion or molding) step, whereas the term “connected” without the modifier “integrally” is intended to mean the two related structures are either integrally connected, or are separately formed and then connected by means of a fastener, weld or other connective mechanism. Various modifications to the preferred embodiment will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

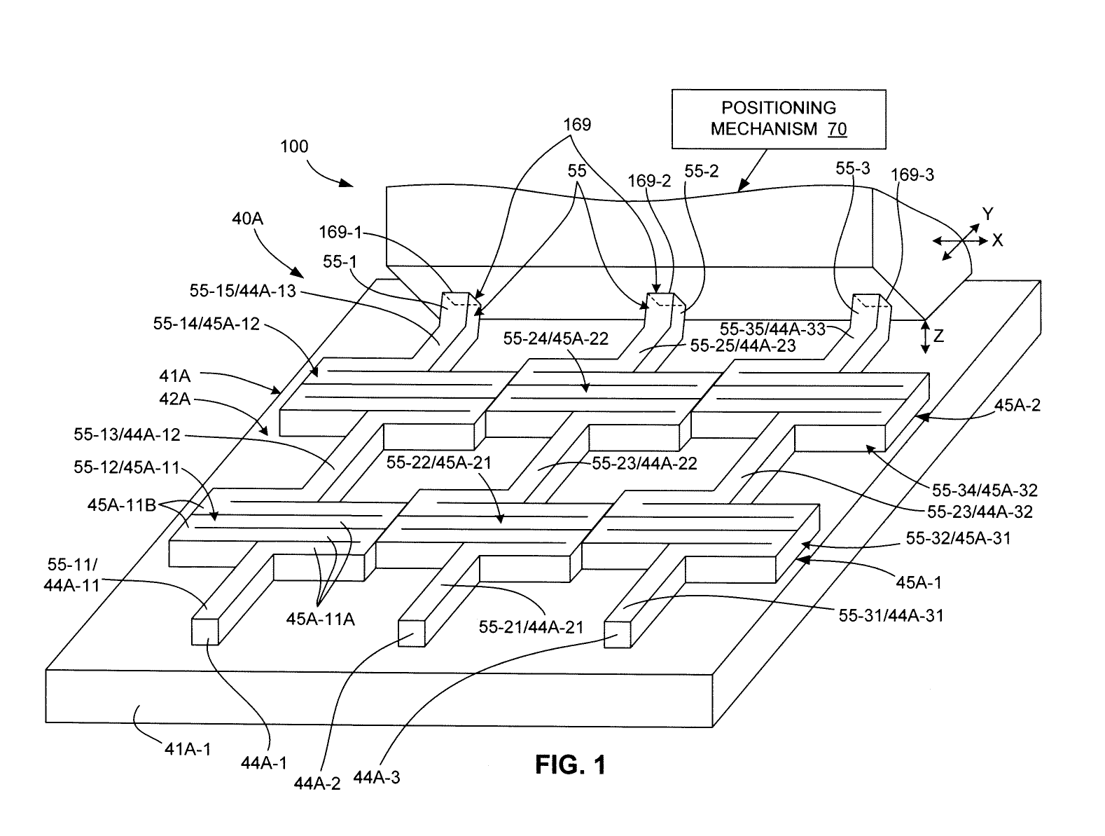

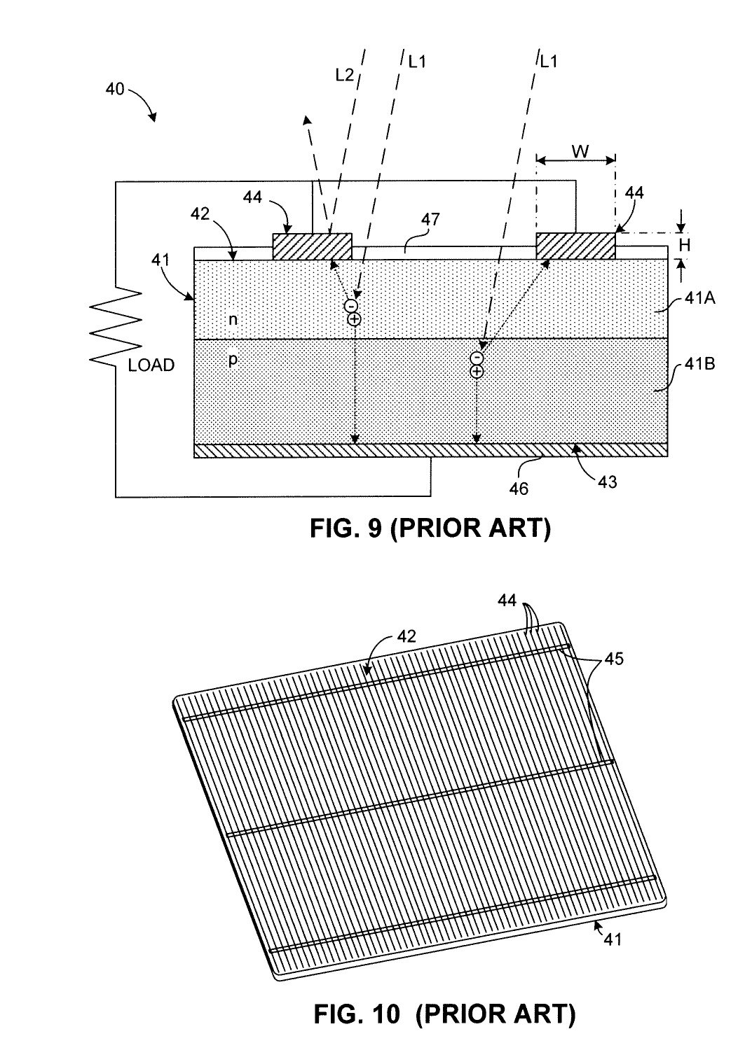

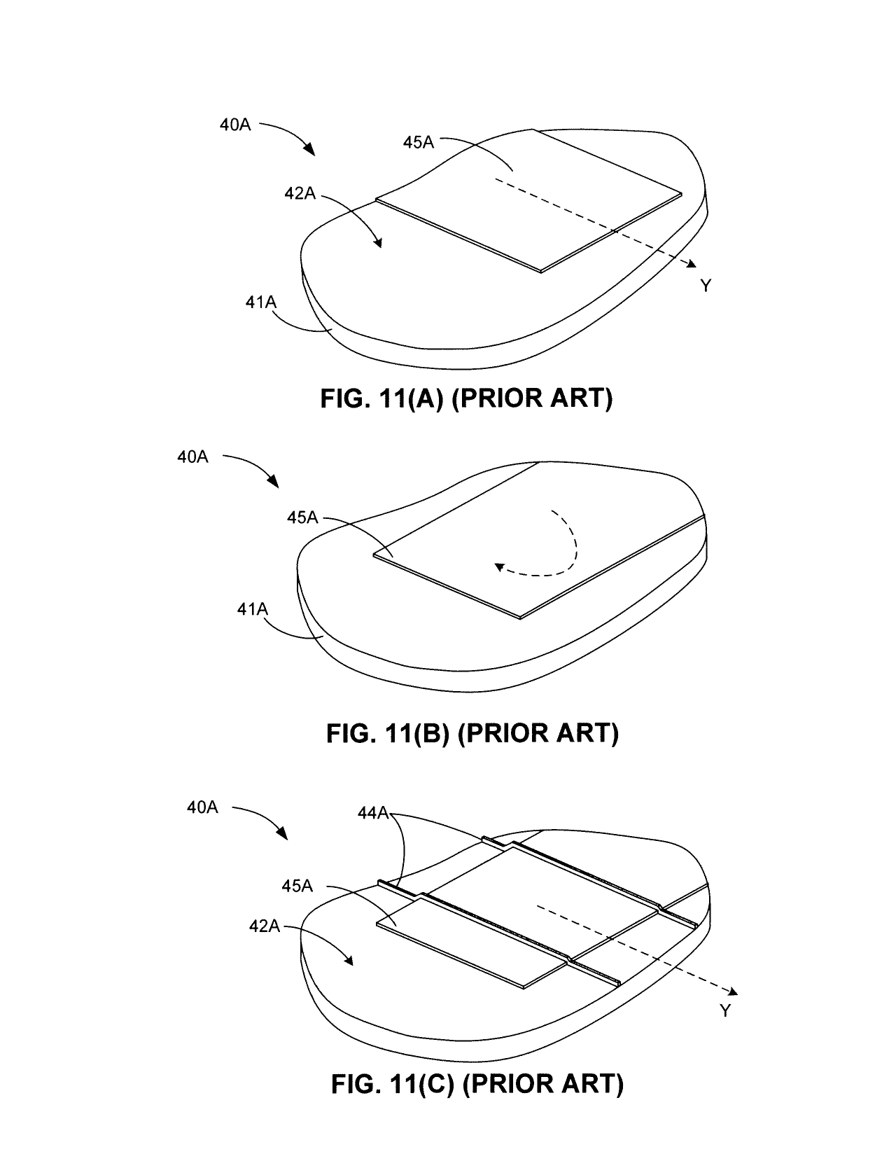

FIG. 1 is a perspective view showing the front contact pattern of simplified solar cell 40A formed on an upper surface 42A of a semiconductor substrate 41 in accordance with an embodiment of the present invention. Similar to conventional solar cell 40 (described above with reference to FIGS. 9 and 10), the front contact pattern of solar cell 40A consists of narrower parallel gridlines 44A-1, 44A-2 and 44A-3 extending in a Y-axis (first) direction, and relatively wide bus bar structures 45A-1 and 45A-2 that extend in a X-axis (second) direction (i.e., generally perpendicular to gridline 44A-1 to 44A-3). Also similar to conventional solar cell 40, gridlines 44A-1 to 44A-3 collect electrons (current) from substrate 41A as described above, and bus bar structures 45A-1 and 45A-2 gather current from gridlines 44A-1 to 44A-3. In a photovoltaic module, bus bar structures 45A-1 and 45A-2 serve as points to which metal ribbons (not shown) are attached, typically by soldering, with the ribbon being used to electrically connect one cell to another.

In accordance with an aspect of the present invention, solar cell 40A differs from conventional solar cell 40 (described above) in that both gridlines 44A-1, 44A-2 and 44A-3 and bus bar structures 45A-1 and 45A-2 are produced by integral extruded structures (beads) 55 during a single pass of a micro-extrusion printhead assembly 100 over substrate 41A in the Y-axis direction. Referring to the upper portion of FIG. 1, printhead assembly 100 defines nozzle outlets 169-1 to 169-3 from which beads 55-1 to 55-3 are respectively extruded. Beads 55-1 to 55-3 comprise an electrically conductive material that is forced through nozzle outlets 169-1 to 169-3 in the manner described below. As indicated by continuous extruded structures 55-1 to 55-3 disposed on upper surface 42A and as described in additional detail below, beads 55 are extruded continuously during the formation of both gridlines 44A-1, 44A-2 and 44A-3 and bus bar structures 45A-1 and 45A-2.

As shown in FIG. 1 and described in additional detail below, printhead assembly 100 is moved relative to substrate 41A by a positioning mechanism 70 during the extrusion process to produce substantially collinear gridline sections that form gridlines 44A-1, 44A-2 and 44A-3, and intervening switchback sections that form bus bar structures 45A-1 and 45A-2. For example, continuous extruded structure 55-1 includes a first section 55-11 that forms a first elongated, substantially straight gridline section 44A-11, a second section 55-12 that forms a first serpentine-shaped switchback section 45A-11, a third section 55-13 that forms a second gridline section 44A-12, a fourth section 55-14 that forms a second switchback section 45A-12, a fifth section 55-15 that forms third gridline section 44A-13. Similarly, continuous extruded structures 55-2 and 55-3 respectively include first sections 55-21 and 55-31 forming first gridline sections 44A-21 and 44A-31, second sections 55-22 and 55-32 forming first switchback sections 45A-21 and 45A-31, third sections 55-23 and 55-23 forming second gridline sections 44A-22 and 44A-32, fourth sections 55-24 and 55-34 forming second switchback sections 45A-22 and 45A-32, and fifth sections 55-25 and 55-35 forming third gridline sections 44A-23 and 44A-33. Each collinear set of gridline sections collectively forms an associated gridline extending across substrate 41A in the Y-axis direction (e.g., gridlines sections 44A-11, 44A-12 and 44A-13 collectively form gridline 44A-1, gridlines sections 44A-21, 44A-22 and 44A-23 collectively form gridline 44A-2, and gridlines sections 44A-31, 44A-32 and 44A-33 collectively form gridline 44A-3). Similarly, each set of switchback sections aligned in the X-axis direction collectively forms an associated bus bar structure that extends across substrate 41A in the X-axis direction (e.g., switchback sections 45A-11, 45A-12 and 45A-13 collectively form bus bar structure 45A-1, and bus bar sections 45A-21, 45A-22 and 45A-23 collectively form bus bar structure 45A-2).

According to an aspect of the present invention, because integral extruded structures 55-1 to 55-3 are continuously formed during a single pass of printhead assembly 100 over substrate 41A, each switchback section comprises a serpentine-like continuous line of material that is integrally connected between an associated pair of gridline sections. For example, referring to the lower left portion of FIG. 1, switchback section 45A-11 is integrally connected between gridline sections 44A-11 and 44A-12. In particular, a first end of switchback section 45A-11 is integrally connected to (i.e., continuously formed with) gridline section 44A-11, a second end of switchback section 45A-11 is integrally connected to gridline section 44A-12, and a central portion of switchback section 45A-11 includes several switchback segments 45A-11A that extend generally in the X-axis direction, and are integrally connected by way of 180° bend structures 145A-11B.

According to an embodiment of the present invention, a method for producing solar cell 40A includes positioning multi-nozzle extrusion printhead assembly 100 over the surface 42A such that nozzle outlets 169-1 to 169-3 are located adjacent to and parallel with side edge 41A-1, and then, while causing printhead assembly 100 to continuously extrude material (i.e., such that beads 55-1 to 55-3 are directed toward substrate 41A), sequentially moving printhead assembly 100 relative to the target substrate in a manner that alternately forms the gridline segments and switchback segments that are described above. In particular, printhead assembly 100 is first moved in a straight line along the (first) Y-axis direction such that first extrusion line portions 55-11, 55-21 and 55-31 are deposited to respectively form a set of parallel first gridline sections 44A-11, 44A-21 and 44A-31. Next, printhead assembly 100 is reciprocated back and forth in the X-axis (second) direction such that second extrusion line portions 55-12, 55-22 and 55-32 collectively form a first set of bus bar segments 45A-11, 45A-21 and 45A-31 that are aligned in the X-axis direction (i.e., extend generally parallel to edge 41A-1). Note that the extrusion of material forming integral extruded structures 55-1, 55-2 and 55-3 remains continuous during the transition between printing first extrusion line portions 55-11, 55-21 and 55-31 and second extrusion line portions 55-12, 55-22 and 55-32, whereby bus bar segments 45A-11, 45A-21 and 45A-31 are integrally connected to ends of first gridline sections 44A-11, 44A-21 and 44A-31, respectively. Note also that, according to the disclosed embodiment, the movement of printhead assembly 100 in the X-axis direction during the formation of bus bar segments 45A-11, 45A-21 and 45A-31 is selected such that adjacent bus bar segments (e.g., segments 45A-11 and 45A-21) contact each other to form continuous bus bar structure 45A-1 extending in the X-axis direction. Next, printhead assembly 100 is returned to a straight line movement along the Y-axis direction such that third extrusion line portions 55-13, 55-23 and 55-33 are deposited to respectively form a set of parallel second gridline sections 44A-12, 44A-22 and 44A-32. In one embodiment, printhead assembly 100 is positioned relative to substrate 41A during deposition of third extrusion line portions 55-13, 55-23 and 55-33 such that second gridline sections 44A-12, 44A-22 and 44A-32 are respectively aligned with first gridline sections 44A-11, 44A-21 and 44A-31. Printhead assembly is then again reciprocated back and forth in the X-axis (second) direction such that fourth extrusion line portions 55-14, 55-24 and 55-34 collectively form a second set of bus bar segments 45A-12, 45A-22 and 45A-32. Finally, printhead assembly 100 is returned once more to a straight line movement along the Y-axis direction such that fifth extrusion line portions 55-15, 55-25 and 55-35 are deposited to respectively form a set of parallel third gridline sections 44A-13, 44A-23 and 44A-33. The flow of extrusion material through printhead assembly 100 is then terminated.

In accordance with an embodiment of the present invention, positioning mechanism 70 controls the relative movement of printhead assembly 100 and substrate 41A such that printhead assembly 100 moves in the Y-axis direction at a first speed during formation of the gridline sections, and moves in the Y-axis at a second (slower) speed during formation of the bus bar segments. For example, during the first phase of the printing process, printhead assembly 100 is moved in a straight-line along the Y-axis direction at a relatively fast first speed such that first bead portions 55-11, 55-21 and 55-31 are deposited on surface 42A to form first parallel gridline sections 44-11, 44-21 and 44-31. Next, during the second phase of the printing process, movement of printhead assembly 100 in the Y-axis direction is slowed down while printhead assembly 100 is reciprocated back and forth in the X-axis direction, thereby causing second extrusion line portions 55-12, 55-22 and 55-32 to collectively form a first set of bus bar segments 45A-11, 45A-12 and 45A-13 that are aligned in the X-axis direction (i.e., extend generally parallel to edge 41A-1). Then, at the end of the second phase and the beginning of the third printing phase, movement of printhead assembly 100 in the Y-axis direction is again sped up to the first speed to facilitate rapid printing of third bead portions 55-13, 55-23 and 55-33, thereby forming second gridline sections 44-12, 44-22 and 44-32 that extend parallel to (and respectively collinear with) first gridline sections 44-11, 44-21 and 44-31.

As set forth above, a preferred embodiment of the present invention involves the formation of gridlines and bus bar structures using a micro-extrusion system. An exemplary micro-extrusion system is set forth below.

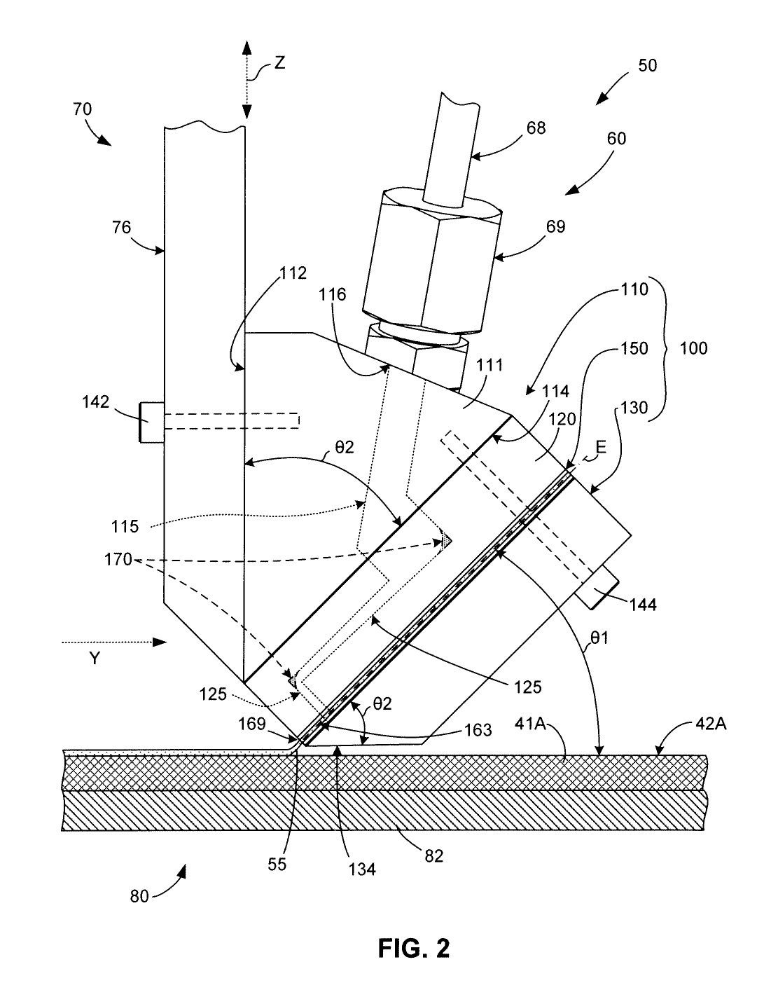

FIG. 2 is a simplified side view showing a portion of a generalized micro-extrusion system 50 for performing the extrusion printing process in accordance with a specific embodiment of the present invention. Micro-extrusion system 50 includes a material feed system 60 that is operably coupled to extrusion printhead assembly 100 (mentioned above with reference to FIG. 1) by way of at least one feedpipe 68 and an associated fastener 69. The materials are applied through pushing and/or drawing techniques (e.g., hot and cold) in which the materials are pushed (e.g., squeezed, etc.) and/or drawn (e.g., via a vacuum, etc.) through extrusion printhead assembly 100, and nozzle outlets 169 that are respectively defined in a lower portion of printhead assembly 100. Micro-extrusion system 50 also includes a X-Y-Z-axis positioning mechanism 70 including a mounting plate 76 for rigidly supporting and positioning printhead assembly 100 relative to substrate 41A, and a base 80 including a platform 82 for supporting substrate 41A in a stationary position as printhead assembly 100 is moved in a predetermined (e.g., Y-axis) direction over substrate 41A. In alternative embodiment, printhead assembly 100 is stationary and base 80 includes an X-Y axis positioning mechanism (shown in dashed lines) for moving substrate 41A under printhead assembly 100. In either case, an electronic controller (e.g., a PC or other computer) supplies control signals to the positioning mechanism using known techniques such that the positioning mechanism is caused to perform the novel printing process described herein.

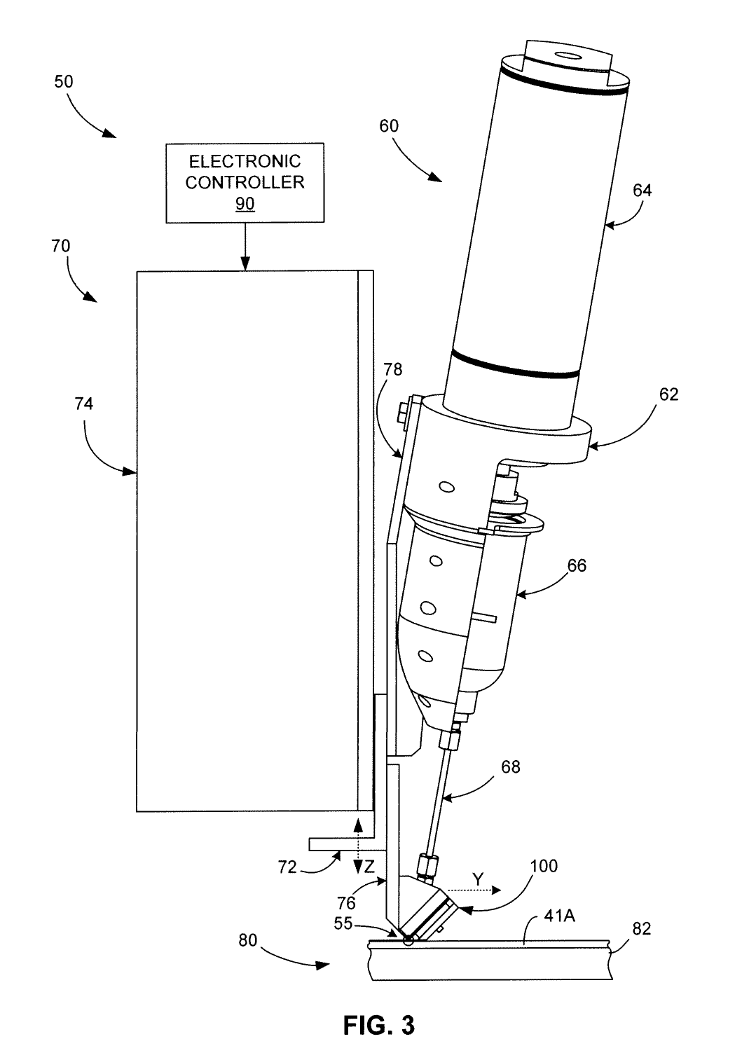

FIG. 3 shows material feed system 60, X-Y-Z-axis positioning mechanism 70 and base 80 of micro-extrusion system 50 in additional detail. The assembly shown in FIG. 3 represents an experimental arrangement utilized to produce solar cells on a small scale, and those skilled in the art will recognize that other arrangements would typically be used to produce solar cells on a larger scale. Referring to the upper right portion of FIG. 3, material feed system 60 includes a housing 62 that supports a pneumatic cylinder 64, which is operably coupled to a cartridge 66 such that material is forced from cartridge 66 through feedpipe 68 into printhead assembly 100. Referring to the left side of FIG. 3, X-Y-Z-axis positioning mechanism 70 includes a Z-axis stage 72 that is movable in the Z-axis (vertical) direction relative to target substrate 41A by way of a housing/actuator 74 in response to control signals received from an electronic controller 90. Mounting plate 76 is rigidly connected to a lower end of Z-axis stage 72 and supports printhead assembly 100, and a mounting frame 78 is rigidly connected to and extends upward from Z-axis stage 72 and supports pneumatic cylinder 64 and cartridge 66. Referring to the lower portion of FIG. 3, base 80 includes supporting platform 82, which supports target substrate 41A as an X-Y mechanism moves printhead assembly 100 in the X-axis and Y-axis directions (as well as a couple of rotational axes) over the upper surface of substrate 41A in accordance with the techniques described herein.

As shown in FIG. 2 and in exploded form in FIG. 4, layered micro-extrusion printhead assembly 100 includes a first (back) plate structure 110, a second (front) plate structure 130, and a layered nozzle structure 150 connected therebetween. Back plate structure 110 and front plate structure 130 serve to guide the extrusion material from an inlet port 116 to layered nozzle structure 150, and to rigidly support layered nozzle structure 150 such that extrusion nozzles 163 defined in layered nozzle structure 150 are pointed toward substrate 41A at a predetermined tilted angle θ1 (e.g., 45°), whereby extruded material traveling down each extrusion nozzle 163 toward its corresponding nozzle orifice 169 is directed toward target substrate 41A.

Each of back plate structure 110 and front plate structure 130 includes one or more integrally molded or machined metal parts. In the disclosed embodiment, back plate structure 110 includes an angled back plate 111 and a back plenum 120, and front plate structure 130 includes a single-piece metal plate. Angled back plate 111 includes a front surface 112, a side surface 113, and a back surface 114, with front surface 112 and back surface 114 forming a predetermined angle 82 (e.g., 45°; shown in FIG. 1). Angled back plate 111 also defines a bore 115 that extends from a threaded countersunk bore inlet 116 defined in side wall 113 to a bore outlet 117 defined in back surface 114. Back plenum 120 includes parallel front surface 122 and back surface 124, and defines a conduit 125 having an inlet 126 defined through front surface 122, and an outlet 127 defined in back surface 124. As described below, bore 115 and plenum 125 cooperate to feed extrusion material to layered nozzle structure 150. Front plate structure 130 includes a front surface 132 and a beveled lower surface 134 that form predetermined angle θ2 (shown in FIG. 1).

Layered nozzle structure 150 includes two or more stacked plates (e.g., a metal such as aluminum, steel or plastic) that combine to form one or more extrusion nozzles 163. In the embodiment shown in FIG. 4, layered nozzle structure 150 includes a top nozzle plate 153, a bottom nozzle plate 156, and a nozzle outlet plate 160 sandwiched between top nozzle plate 153 and bottom nozzle plate 156. Top nozzle plate 153 defines an inlet port (through hole) 155, and has a (first) front edge 158-1. Bottom nozzle plate 156 is a substantially solid (i.e., continuous) plate having a (third) front edge 158-2. Nozzle outlet plate 160 includes a (second) front edge 168 and defines an elongated nozzle channel 162 extending in a predetermined first flow direction F1 from a closed end 165 to an nozzle orifice 169 defined through front edge 168. When operably assembled (e.g., as shown in FIG. 6), nozzle outlet plate 160 is sandwiched between top nozzle plate 153 and bottom nozzle plate 156 such that elongated nozzle channel 162, a front portion 154 of top nozzle plate 153, and a front portion 157 of bottom nozzle plate 156 combine to define elongated extrusion nozzle 163 that extends from closed end 165 to nozzle orifice 169. In addition, top nozzle plate 153 is mounted on nozzle outlet plate 160 such that inlet port 155 is aligned with closed end 165 of elongated channel 162, whereby extrusion material forced through inlet port 155 flows in direction F1 along extrusion nozzle 163, and exits from layered nozzle structure 150 by way of nozzle orifice 169 to form bead 55 that is deposited on substrate 41A.

Referring again to FIG. 2, when operably assembled and mounted onto micro-extrusion system 50, angled back plate 111 of printhead assembly 100 is rigidly connected to mounting plate 76 by way of one or more fasteners (e.g., machine screws) 142 such that beveled surface 134 of front plate structure 130 is positioned close to parallel to upper surface 42A of target substrate 41A. One or more second fasteners 144 are utilized to connect front plate structure 130 to back plate structure 110 with layered nozzle structure 150 pressed between the back surface of front plate structure 130 and the back surface of back plenum 120. In addition, material feed system 60 is operably coupled to bore 115 by way of feedpipe 68 and fastener 69 using known techniques, and extrusion material forced into bore 115 is channeled to layered nozzle structure 150 by way of conduit 125.

In a preferred embodiment, as shown in FIG. 2, a hardenable material is injected into bore 115 and conduit 125 of printhead assembly 100 in the manner described in co-owned and co-pending U.S. patent application Ser. No. 12/267,194 entitled “DEAD VOLUME REMOVAL FROM AN EXTRUSION PRINTHEAD”, which is incorporated herein by reference in its entirety. This hardenable material forms portions 170 that fill any dead zones of conduit 125 that could otherwise trap the extrusion material and lead to clogs.

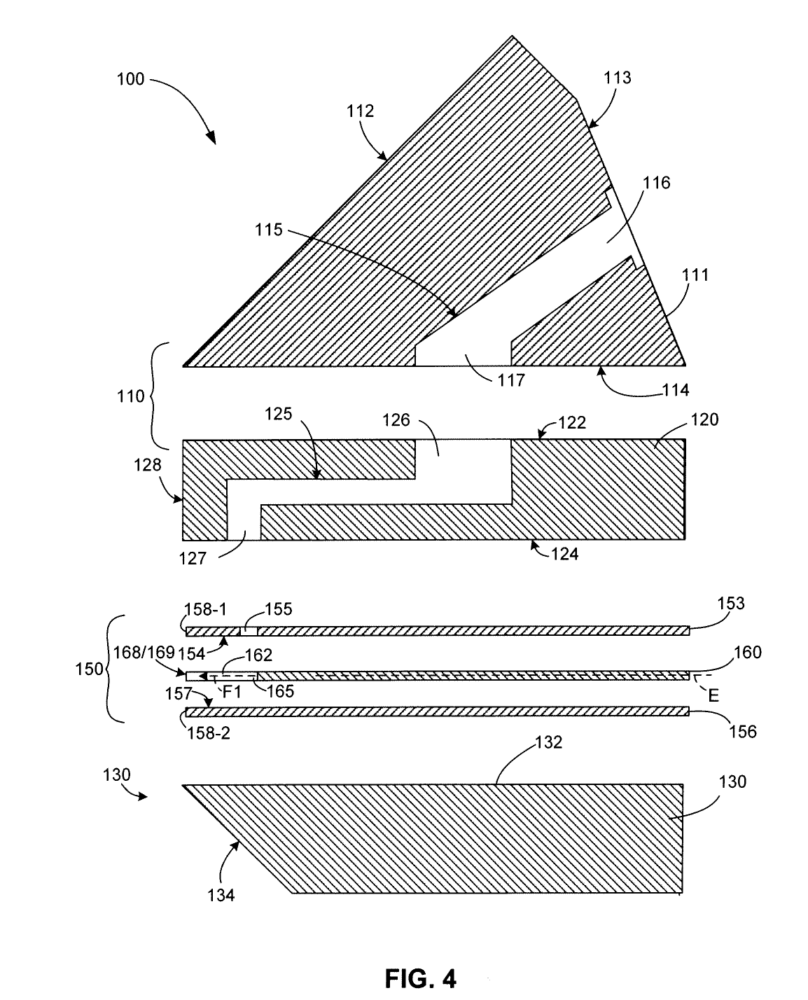

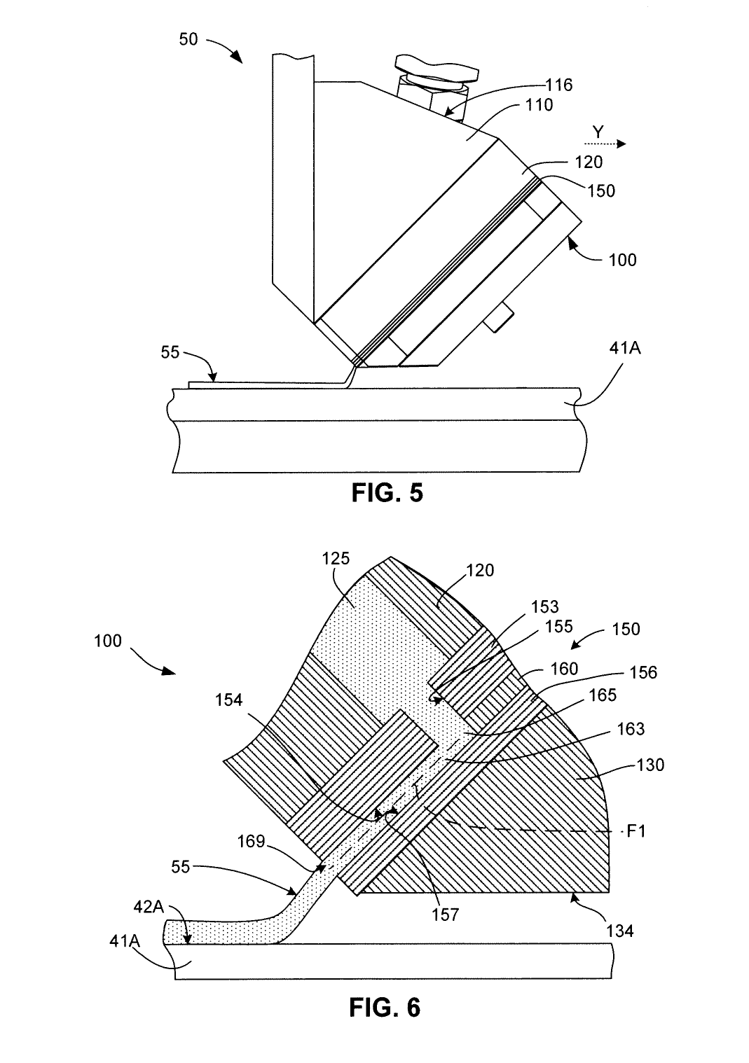

FIG. 5 is a partial side view showing a portion of system 50 including printhead assembly 100, and FIG. 6 is a simplified cross-sectional side view showing a portion of printhead assembly 100 during operation. As indicated in these figures, during operation printhead assembly 100 is maintained above substrate 41A and moved in the Y-axis direction as extruded material is injected through inlet port 116 into bottom plate assembly 110, and through back plenum 120 to layered nozzle assembly 150, from which beads 55 are extruded onto surface 42A. As shown in additional detail in FIG. 6, the extrusion material exiting conduit 125 of back plenum 120 enters the closed end of nozzle 163 by way of inlet 155 and closed end 165 (both shown in FIG. 3) of nozzle 163, and flows in direction F1 down nozzle 163 toward outlet 169. The extrusion material flowing in the nozzle 163 is directed through the nozzle opening 169. Referring back to FIG. 2, the extruded material is guided at the tilted angle θ2 as it exits nozzle orifice 169, thus being directed toward substrate 41A in a manner that facilitates high volume solar cell production.

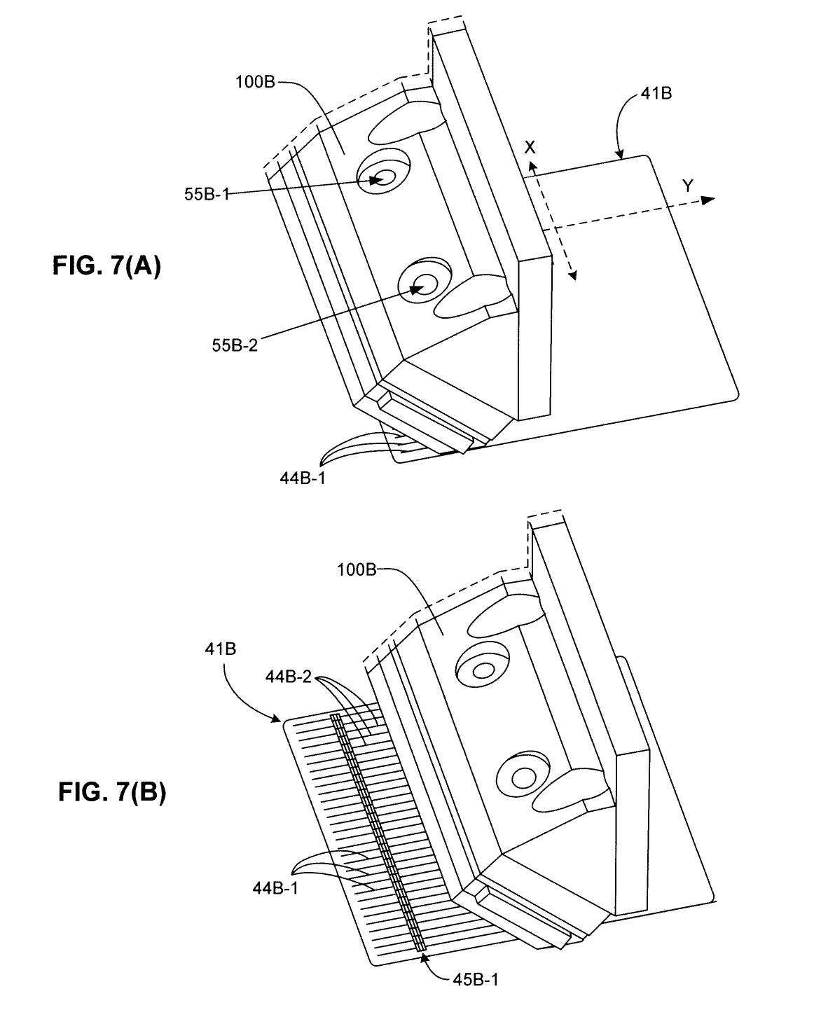

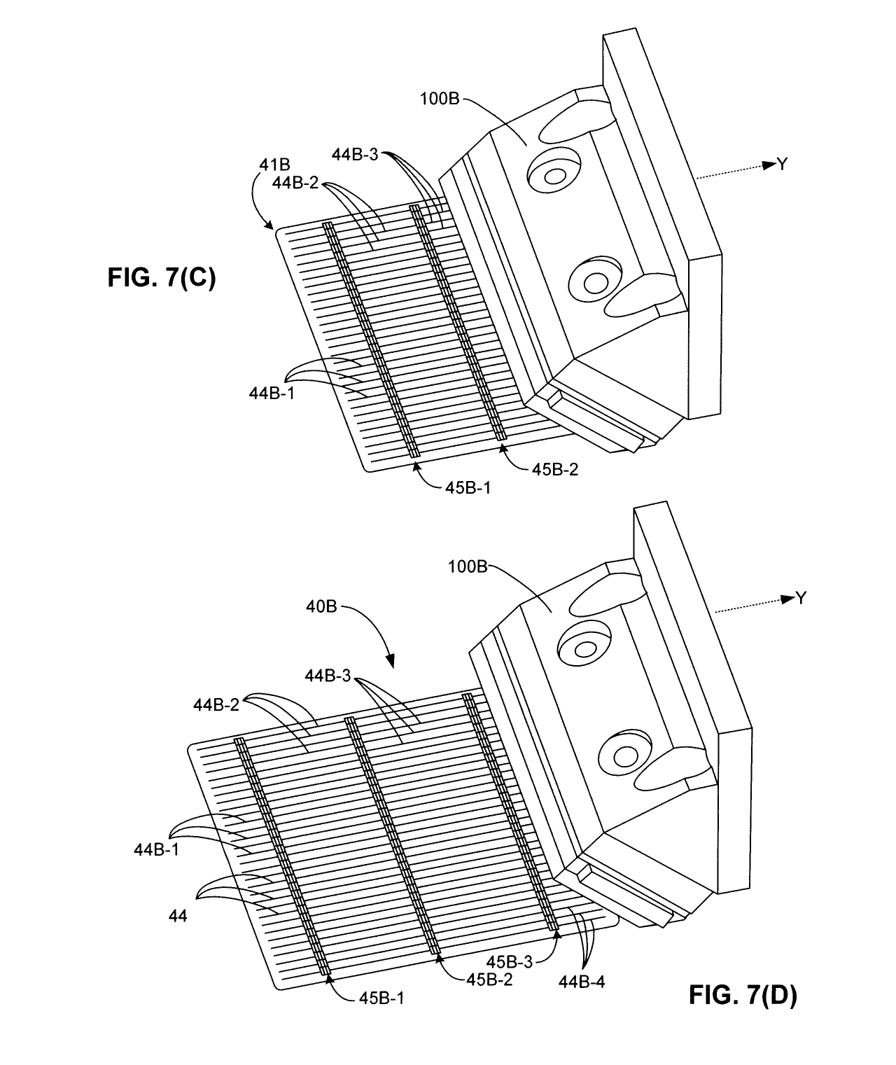

FIGS. 7(A) to 7(D) illustrate the production of the front contact pattern for a solar cell 40B according to another specific embodiment of the present invention. The production process illustrated in these figures utilizes a co-extrusion printhead assembly 100B, which is similar to printhead assembly 100B (described above), but simultaneously extrudes a metal-bearing (gridline) material 51B-1 and a non-conductive sacrificial material 51B-2 using co-extrusion techniques such as those described in co-owned and co-pending U.S. patent application Ser. No. 12/267,069, entitled “DIRECTIONAL EXTRUDED BEAD CONTROL”, which is incorporated herein by reference in its entirety. As with the previously described embodiments, the printing process illustrated in FIGS. 7(A) to 7(D) involves a single pass of printhead 100B over the surface of substrate 41B. As indicated in FIG. 7(A), after printing first gridline sections 44B-1, printhead 100B is reciprocated (oscillated) in the X-axis direction in order to print switchback sections that form first bus bar structure 45B-1 (shown in FIG. 7(B)). Similarly, as indicated in FIGS. 7(C) and 7(D), after printing second gridline sections 443-2, printhead 100B is again reciprocated in the X-axis direction to print second bus bar structure 45B-2, then translated in the Y-axis direction to print third gridline sections 44B-3, then reciprocated to print third bus bar structures 44B-3, then translated in the Y-axis direction to print fourth gridline sections 44B-4. The resulting solar cell 40B is shown in FIG. 7(D).

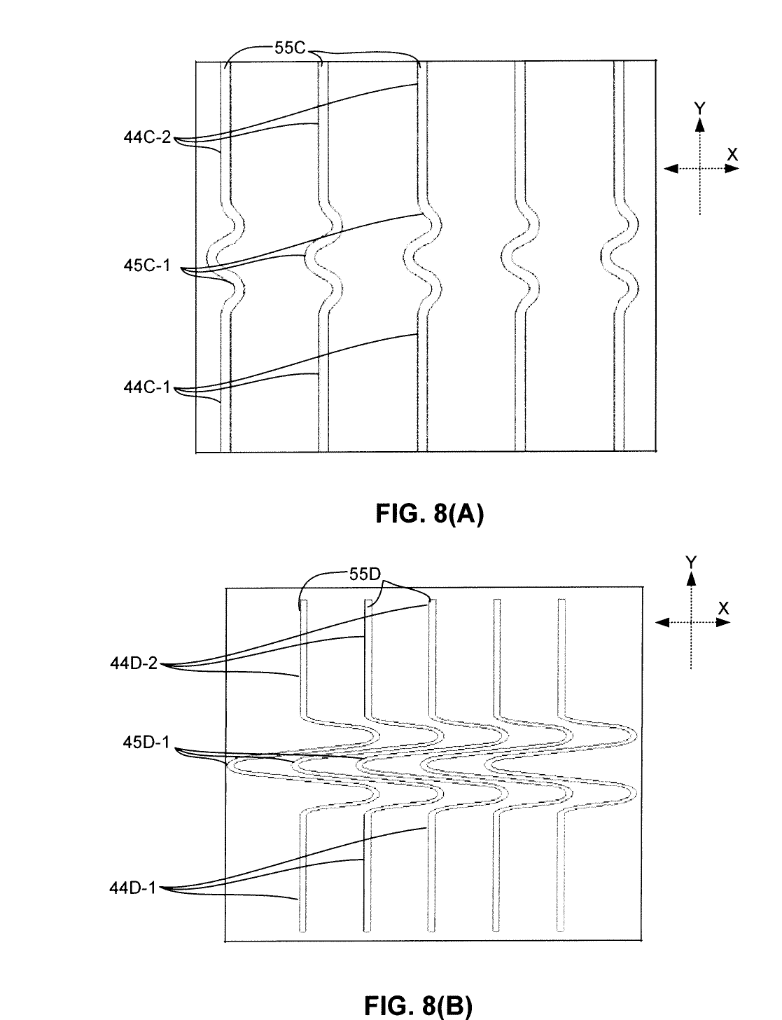

FIGS. 8(A) and 8(B) illustrate exemplary switchback patterns that are generated by extruded lines 55C and 55D in accordance with alternative embodiments of the present invention utilizing techniques similar to those described above. These figures illustrate that by reducing the speed of translation in the Y-axis direction between printing straight sections 44C-1/44C-2 and 44D-1/44D-2, while at the same time oscillating either the device or the printhead in the X-axis direction, a bus bar structure pattern can be defined that is continuous or nearly continuous (e.g., bus bar structure 45D-1; see FIG. 8(B)), or open to various degrees (e.g., bus bar structure 45C-1; see FIG. 8(A)). Such a pattern allows the fingers and the buses to be written in a single pass while allowing additional features to be designed into the bus, for example reducing the use of ink (extruded material) or optimizing the surface area available for subsequent lead wire attachment. Alternatively, the pattern may be pre-defined using laser ablation, the principle of oscillation of the write head or the substrate around the direction of travel being the same as for the direct application of ink.

Although the present invention has been described with respect to certain specific embodiments, it will be clear to those skilled in the art that the inventive features of the present invention are applicable to other embodiments as well, all of which are intended to fall within the scope of the present invention. For example, instead of, or in addition to, oscillating the device or the print head to form the bus areas, the width of the central, metal feature of the extruded line may be varied by altering the relative pressure between the metal-bearing ink and the non-metal bearing ink in the invention described in co-owned and co-pending U.S. patent application Ser. No. 11/282,882, filed Nov. 17, 2005, entitled “Extrusion/Dispensing Systems and Methods”, and in co-owned and co-pending U.S. patent application Ser. No. 11/282,882, filed Nov. 17, 2005, entitled “Extrusion/Dispensing Systems and Methods”, which are incorporated herein by reference in their entirety. Maximizing the width of the metal bearing ink in the bus region, with or without oscillation can be used to provide the solderable bus area required. Some process sequences use a pattern that has been pre-written using a laser to define the contact area. This can also be accomplished using the present invention. Clearly, any number of different patterns can be obtained by appropriate manipulation of the printhead and the device to obtain a pattern that is continuous and may be applied by a single pass of the printhead.

1. A solar cell comprising:
a target substrate having an upper surface and a side edge;
a plurality of parallel gridlines that extend in a first direction across the upper surface of the target substrate; and
one or more bus bar structures that extend in a second direction across the upper surface of the target substrate, the second direction being generally perpendicular to the first direction,
wherein each of the plurality of parallel gridlines includes a plurality of elongated, substantially straight gridline sections extending in the first direction,
wherein each of the one or more bus bar structures comprises a plurality of switchback sections aligned in the second direction,
wherein each switchback section of each of the plurality of switchback sections is connected between an associated pair of said plurality of gridline sections, and
wherein said each switchback section and said associated pair of said plurality of gridline sections comprises an integral extruded structure.

2. The solar cell according to claim 1, wherein said each switchback section comprises a continuous line of material having a first end connected to an associated first gridline section of said associated pair of said plurality of gridline sections, a second end connected to an associated second gridline section of said associated pair of said plurality of gridline sections, and a central portion comprising a plurality of switchback segments that extend generally in the second direction.

3. A method for forming on a target substrate a plurality of parallel gridlines that extend in a first direction across a surface of the target substrate, and one or more bus bar structures that extend in a second direction across the surface of the target substrate, the second direction being generally perpendicular to the first direction, the method comprising:
positioning a multi-nozzle extrusion printhead assembly over the surface of the target substrate such that a plurality of nozzle outlets of the printhead assembly are positioned adjacent to and parallel with a first edge of the target substrate; and
while causing said printhead assembly to continuously extrude material such that a plurality of beads of said extrusion material are directed toward said target substrate, each said bead being extruded from a corresponding one of said plurality of nozzle outlets, sequentially moving said printhead assembly relative to the target substrate:
in the first direction such that first portions of said extruded beads are deposited on the surface and form parallel first gridline sections extending away from said first edge,
in the second direction such that second portions of said extruded beads are deposited on the surface in a way that collectively forms a first bus bar structure extending generally parallel to said first edge, and
in the first direction such that third portions of said extruded beads are deposited on the surface and form second gridline sections extending parallel to the first gridline sections.

4. The method according to claim 3, wherein moving said printhead assembly relative to the target substrate further comprises positioning said printhead assembly such that each said first gridline section extruded from an associated nozzle outlet is collinear with an associated said second gridline section extruded from said associated nozzle outlet.

5. The method according to claim 3, wherein moving said printhead assembly relative to the target substrate in the second direction further comprises reciprocating said printhead assembly in said second direction a plurality of times, whereby each said bead is deposited on said target substrate in the form of a serpentine-like bus bar segment.

6. The method according to claim 5, wherein moving said printhead assembly relative to the target substrate in the second direction comprises causing a first said bus bar segment extruded from a first nozzle orifice to contact a second said bus bar segment extruded from a second nozzle orifice that is located adjacent to the first nozzle orifice.

7. The method according to claim 5, wherein moving said printhead assembly relative to the target substrate in the second direction comprises depositing each said second portion in a way that is integrally connected to an associated first bus bar structure.

8. The method according to claim 3, wherein moving said printhead assembly relative to the target substrate in the first and second directions comprises depositing said first portions, said second portions and said third portions during a single pass of said printhead assembly over the target substrate.

9. The method according to claim 3,
wherein moving said printhead assembly relative to the target substrate in the first direction comprises moving said printhead assembly in said first direction at a first speed, and
wherein moving said printhead assembly relative to the target substrate in the second direction comprises moving said printhead assembly in said first direction at a second speed, said second speed being slower than said first speed.

10. A method for forming on a target substrate a plurality of parallel gridlines that extend in a first direction across a surface of the target substrate and one or more bus bar structures that extend in a second direction across a surface of the target substrate, the second direction being generally perpendicular to the first direction, the method comprising:
positioning a multi-nozzle extrusion printhead assembly over the surface of the target substrate such that a plurality of nozzle outlets of the printhead assembly are positioned adjacent to and parallel with a first edge of the target substrate; and
while continuously extruding material from said printhead assembly such that a plurality of beads of said extrusion material are directed toward said target substrate, each said bead being extruded from a corresponding one of said plurality of nozzle outlets:
moving said printhead assembly relative to the target substrate in the first direction at a first speed such that first portions of said extruded beads are deposited on the surface and form parallel first gridline sections extending away from said first edge;
moving said printhead assembly relative to the target substrate in the first direction at a second speed, said second speed being slower than said first speed, while reciprocating said printhead assembly relative to the target substrate in the second direction such that second portions of said extruded beads are deposited on the surface in a way that collectively forms a first bus bar structure extending generally parallel to said first edge; and
moving said printhead assembly relative to the target substrate in the first direction at the first speed such that third portions of said extruded beads are deposited on the surface and form second gridline sections extending parallel to the first gridline sections.

11. The method according to claim 10, wherein moving said printhead assembly relative to the target substrate further comprises positioning said printhead assembly such that each said first gridline section extruded from an associated nozzle outlet is collinear with an associated said second gridline section extruded from said associated nozzle outlet.

12. The method according to claim 10, wherein moving said printhead assembly relative to the target substrate in the second direction further comprises reciprocating said printhead assembly in said second direction a plurality of times, whereby each said bead is deposited on said target substrate in the form of a serpentine-like bus bar segment.

13. The method according to claim 12, wherein moving said printhead assembly relative to the target substrate in the second direction comprises causing a first said bus bar segment extruded from a first nozzle orifice to contact a second said bus bar segment extruded from a second nozzle orifice that is located adjacent to the first nozzle orifice.

14. The method according to claim 12, wherein moving said printhead assembly relative to the target substrate in the second direction comprises depositing each said second portion in a way that is integrally connected to an associated first bus bar structure.

15. The method according to claim 10, wherein moving said printhead assembly relative to the target substrate in the first and second directions comprises depositing said first portions, said second portions and said third portions during a single pass of said printhead assembly over the target substrate.

16. A method similar to claim 3 in which the pattern is formed using a single, continuous pass of laser.
